(19) United States
(12) Patent Application Publication
(10) Pub. No.: US 2024/0107814 A1
(43) Pub. Date: Mar. 28, 2024

(54) PIXEL-DEFINING LAYER AND DISPLAY DEVICE INCLUDING THE SAME

(71) Applicant: Samsung Display Co., Ltd., Yongin-si (KR)

(72) Inventor: Chungi You, Yongin-si (KR)

(21) Appl. No.: 18/354,896

(22) Filed: Jul. 19, 2023

(30) Foreign Application Priority Data
Sep. 26, 2022 (KR) 10-2022-0121971

(51) Int. Cl. H10K 59/122; H10K 59/131

(52) U.S. Cl. CPC H10K 59/122; H10K 59/131

(57) ABSTRACT

A display device includes a substrate, a wiring layer on the substrate and including a first wire and a second wire extending along a first direction and spaced apart from each other along a second direction crossing the first direction, planarization layer on the wiring layer, a pixel electrode which is on the planarization layer, a pixel-defining layer on the planarization layer and overlapping the pixel electrode, and a pixel opening which is defined in the pixel-defining layer and exposes the pixel electrode to outside the pixel-defining layer. The pixel-defining layer includes edges which define the pixel opening, and among the edges of the pixel-defining layer, a 1-1 edge and a 1-2 edge each extends along the first direction, the 1-1 edge and the 1-2 edge are spaced apart from each other along the second direction, and the 1-1 edge overlaps the first wire.

This application claims priority to Korean Patent Application No. 10-2022-0121971, filed on Sep. 26, 2022, and all the benefits accruing therefrom under 35 U.S.C. § 119, the disclosure of which is incorporated by reference herein in its entirety.

### BACKGROUND

### 1. Field

One or more embodiments relate to a display device. More particularly, one or more embodiments relate to a display device capable of preventing or reducing reflow that occurs during the manufacture of a pixel-defining layer.

### 2. Description of the Related Art

A display device receives information regarding an image and displays the image. A pixel-defining layer included in the display device defines a pixel area in which a pixel electrode is disposed and may be adjacent to wiring under and connected to the pixel electrode.

### SUMMARY

In providing of a display device, a reflow phenomenon may occur at the edges of a pixel-defining layer due to heat applied when the pixel-defining layer is formed. The degree of the reflow phenomenon may vary at the edges of the pixel-defining layer since the degree of dissipation of heat applied to the wiring under and connected to a pixel electrode may vary. Thus, a problem in which the edges of the pixel-defining layer are uneven and not smooth may occur.

To solve various problems including the above problem, one or more embodiments include a display device capable of preventing or reducing reflow that occurs during the manufacture of a pixel-defining layer. However, such a technical problem is an example, and one or more embodiments are not limited thereto.

Additional aspects will be set forth in part in the description which follows and, in part, will be apparent from the description, or may be learned by practice of the presented embodiments of the disclosure.

To prevent or reduce reflow that occurs during the manufacture of a pixel-defining layer, a display device includes a substrate, a first wire arranged above the substrate and extending in a first direction, a second wire arranged above the substrate, extending in the first direction, apart from the first wire in a second direction perpendicular to the first direction, and having the same layer structure as the first wire, a planarization layer covering the first wire and the second wire, a first pixel electrode on the planarization layer, and a pixel-defining layer having a first pixel opening exposing a central portion of the first pixel electrode, arranged on the planarization layer to cover edges of the first pixel electrode, and including a 1-1 edge extending in the first direction and a 1-2 edge apart from the 1-1 edge among edges of the first pixel opening when viewed from a direction vertical to the substrate, where the 1-1 edge overlaps the first wire.

The 1-2 edge may overlap the second wire.

A portion of at least one of the 1-1 edge and the 1-2 edge may be recessed into the first pixel opening. For example, one edge among the 1-1 edge and the 1-2 edge may include a protruded portion which protrudes toward the other edge among the 1-1 edge and the 1-2 edge.

When viewed from the direction vertical to the substrate, a shape of the first wire may correspond to a shape of the 1-1 edge, and a shape of the second wire may correspond to a shape of the 1-2 edge.

The display device may further include a third wire arranged above the substrate, extending in the first direction, apart from the second wire and opposite to the first wire with respect to the second wire, and having the same layer structure as the first wire, and a fourth wire arranged above the substrate, extending in the first direction, apart from the third wire and opposite to the first wire with respect to the third wire, and having the same layer structure as the first wire, where the planarization layer may cover the third wire and the fourth wire.

The display device may further include a second pixel electrode on the planarization layer and apart from the first pixel electrode in the second direction, where the pixel-defining layer may have a second pixel opening exposing a central portion of the second pixel electrode, may be arranged on the planarization layer to cover edges of the second pixel electrode, and may include a 2-1 edge extending in the first direction among edges of the second pixel opening when viewed from the direction vertical to the substrate, where the 2-1 edge may overlap the third wire.

The pixel-defining layer may include a 2-2 edge extending in the first direction and apart from the 2-1 edge among the edges of the second pixel opening when viewed from the direction vertical to the substrate, where the 2-2 edge may overlap the fourth wire.

The display device may further include a second pixel electrode on the planarization layer and apart from the first pixel electrode, where the pixel-defining layer may have a second pixel opening exposing a central portion of the second pixel electrode and may be arranged on the planarization layer to cover edges of the second pixel electrode. The pixel electrode may include a 2-1 edge extending in the first direction among edges of the second pixel opening when viewed from the direction vertical to the substrate and a 2-2 edge extending in the first direction and apart from the 2-1 edge among the edges of the second pixel opening when viewed from the direction vertical to the substrate. When viewed from the direction vertical to the substrate, the third wire may be between the 2-1 edge and the 2-2 edge and apart from the 2-1 edge and the 2-2 edge.

When viewed from the direction vertical to the substrate, the fourth wire may be between the 2-1 edge and the 2-2 edge, apart from the 2-1 edge and the 2-2 edge, and apart from the third wire.

The display device may further include a third pixel electrode on the planarization layer and apart from the first pixel electrode in the first direction, where the pixel-defining layer may have a third pixel opening exposing a central portion of the third pixel electrode, may be arranged on the planarization layer to cover edges of the third pixel electrode, and may include a 3-1 edge extending in the first direction among edges of the third pixel opening when viewed from the direction vertical to the substrate. The 3-1 edge may overlap the first wire.

The pixel-defining layer may include a 3-2 edge extending in the first direction and apart from the 3-1 edge among the edges of the third pixel opening when viewed from the direction vertical to the substrate, where the 3-2 edge may overlap the second wire.

The display device may further include an interlayer insulating layer arranged above the substrate, a fifth wire arranged on the interlayer insulating layer and extending in the second direction, a sixth wire arranged on the interlayer insulating layer, extending in the second direction, apart from the fifth wire in the first direction, and having the same layer structure as the fifth wire, and an organic insulating layer covering the fifth wire and the sixth wire and arranged under the first wire and the second wire.

The pixel-defining layer may include a 1-3 edge extending in the second direction among the edges of the first pixel opening when viewed from the direction vertical to the substrate and a 1-4 edge extending in the second direction and apart from the 1-3 edge among the edges of the first pixel opening when viewed from the direction vertical to the substrate, where the 1-3 edge may overlap the fifth wire.

The 1-4 edge may overlap the sixth wire.

The fifth wire may be between the 1-3 edge and the 1-4 edge and apart from the 1-3 edge and the 1-4 edge.

The sixth wire may be between the 1-3 edge and the 1-4 edge, apart from the 1-3 edge and the 1-4 edge, and apart from the fifth wire in the first direction.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic plan view of a display device according to an embodiment;

FIG. 2 is a schematic cross-sectional view of a portion of a display device according to an embodiment;

FIG. 3 is a schematic plan view of the vicinity of a pixel opening in the display device of FIG. 1;

FIG. 4 is a schematic plan view of the vicinity of a pixel opening in the display device of FIG. 1;

FIG. 5 is a schematic plan view of the vicinity of a pixel opening in the display device of FIG. 1;

FIG. 6 is a schematic cross-sectional view of a portion of the display device of FIG. 1;

FIG. 7 is a schematic plan view of the vicinity of a pixel opening in the display device of FIG. 6;

FIG. 8 is a schematic plan view of the vicinity of a pixel opening in the display device of FIG. 6;

FIG. 9 is a schematic plan view of the vicinity of a pixel opening in the display device of FIG. 1;

FIG. 10 is a schematic plan view of the vicinity of a pixel opening in the display device of FIG. 1;

FIG. 11 is a schematic plan view of the vicinity of a plurality of pixel openings in the display device of FIG. 1;

FIG. 12 is a schematic cross-sectional view of a portion of a display device according to the present embodiment;

FIG. 13 is a schematic plan view of the vicinity of a pixel opening in the display device of FIG. 12;

FIG. 14 is a schematic plan view of the vicinity of a pixel opening in the display device of FIG. 12; and

FIG. 15 is a schematic plan view of the vicinity of a plurality of pixel openings in the display device of FIG. 1.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As the present description allows for various changes and numerous embodiments, embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof are omitted. Herein, a reference number labeling a singular form of an element within the figures may be used to reference a plurality of the singular element within the text of the disclosure. It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that, when an element, such as a layer, a film, a region, or a plate, is referred to as being related to another element such as being “on” another element, it may be “directly on” the other element, or intervening elements may be present therebetween. In contrast, when an element, such as a layer, a film, a region, or a plate, is referred to as being related to another element such as being “directly on” another element, no intervening elements are present therebetween.

In addition, sizes of elements in the drawings may be exaggerated or reduced for convenience of explanation. For example, since sizes and thicknesses of elements in the drawings are arbitrarily illustrated for convenience of explanation, the following embodiments are not limited thereto.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are crossing or intersecting but not perpendicular to one another.

Hereinafter, a display device according to an embodiment will be described in detail based on the above descriptions.

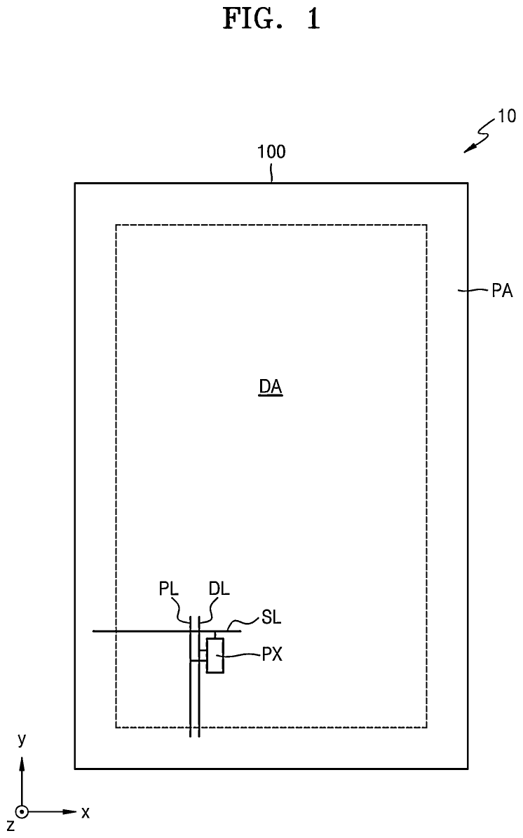

FIG. 1 is a schematic plan view of a display device according to an embodiment.

As shown in FIG. 1, a display device according to an embodiment may include a display panel 10. The display device may be any device such as an electronic device including the display panel 10. For example, the display device may be a variety of devices, such as a smartphone, a tablet, a laptop, a television, or a billboard. A display device according to an embodiment includes thin-film transistors and a capacitor. The thin-film transistors and the capacitor may be implemented by various conductive layers and various insulating layers.

The display panel 10 includes a display area DA and a peripheral area PA which is located outside the display area DA. FIG. 1 shows the display area DA having a rectangular shape (e.g., a planar shape of a rectangle). However, one or more embodiments are not limited thereto. The display area DA may have various planar shapes, for example, a circular shape, an oval shape, a polygonal shape, or a shape of a certain form.

The display area DA is a portion where an image is displayed, and may have a pixel PX provided in plural including a plurality of pixels arranged therein. Each pixel PX may include a display element, such as an organic light-emitting diode. Each pixel PX may generate and/or emit, for example, red, green, or blue light. The pixel PX may be connected to a pixel circuit including a thin-film transistor and a storage capacitor. The pixel circuit may be connected to or include a scan line SL configured to transmit a scan signal, a data line DL crossing the scan line SL and configured to transmit a data signal, and a driving voltage line PL configured to supply a driving voltage. The aforementioned elements of the pixel circuit may be provide in plural to define a pixel circuit layer, without being limited thereto.

The scan line SL may extend in a direction x (hereinafter, a second direction), and the data line DL and the driving voltage line PL may extend in a direction y (hereinafter, a first direction). A plane may be defined by the first and second directions crossing each other. A third direction (hereinafter, a direction z) may cross the plane, and cross each of the first and second directions. A thickness of the display device, the display panel 10 and various components or layers of these features may be defined along the third direction (hereinafter, a thickness direction).

The pixel PX may emit light having a luminance corresponding to an electrical signal from an electrically connected pixel circuit which is connected to the pixel PX. The display area DA may display an image through light emitted from the pixel PX. For reference, the pixel PX may be defined as an emission area (e.g., a light emission area) which emits light having one color among red, green, and blue as described above.

The peripheral area PA is an area where the pixels PX are not arranged, and may be an area where an image is not displayed (e.g., a non-display area). A power supply line for driving the pixel PX may be located in the peripheral area PA. In addition, pads (e.g., terminal pads) may be arranged in the peripheral area PA. A printed circuit board as a component external to the display panel 10 and including a driving circuit portion or an integrated circuit device such as a driver IC, may be electrically connected to the display panel 10 at the pads.

For reference, since the display panel 10 includes a substrate 100, the substrate 100 may also be stated to have the display area DA and the peripheral area PA. That is, various components or layers of the display device (or the display panel 10) may include a display area DA and a peripheral area PA respectively corresponding to those described above. A detailed description of the substrate 100 will be given later.

In addition, a plurality of transistors may be arranged in the display area DA. In the plurality of transistors, depending on the type (N-type or P-type) and/or operation conditions of a transistor, a first terminal of the transistor may be a source electrode or a drain electrode, and a second terminal of the transistor may be an electrode different from the first terminal. For example, when the first terminal is a source electrode, the second terminal may be a drain electrode.

The plurality of transistors may include a driving transistor, a data writing transistor, a compensation transistor, an initialization transistor, and an emission control transistor. The driving transistor may be connected between the driving voltage line PL and an organic light-emitting diode (OLED) as a display element (or light-emitting element). The data writing transistor may be connected to the data line DL and the driving transistor and may be configured to perform a switching operation for transmitting a data signal transmitted through the data line DL.

The compensation transistor may be turned on according to a scan signal received through the scan line SL, to connect the driving transistor and the OLED to each other, thereby compensating for a threshold voltage of the driving transistor.

The initialization transistor may be turned on according to a scan signal received through the scan line SL, to transfer an initialization voltage to a gate electrode of the driving transistor, thereby initializing the gate electrode of the driving transistor. The scan line SL connected to the initialization transistor may be a separate scan line different from the scan line SL connected to the compensation transistor.

The emission control transistor may be turned on according to an emission control signal received through an emission control line, and as a result, a driving current (e.g., electrical driving current) may flow through the OLED.

The OLED may include a pixel electrode (e.g., an anode) and an opposite electrode (e.g., a cathode), and the opposite electrode may receive a common voltage. The OLED may receive a driving current from the driving transistor and emit light, thereby displaying an image.

Although an organic light-emitting display device is described below as an example of a display device according to an embodiment, a display device described herein is not limited thereto. In an embodiment, the display device described herein may be a display device, such as an inorganic light-emitting display (or an inorganic electroluminescent (EL) display) or a quantum dot light-emitting display. For example, an emission layer of a display element included I n the display device may include an organic material or an inorganic material. Alternatively, the display device may include an emission layer and quantum dots positioned on a path of light emitted from the emission layer.

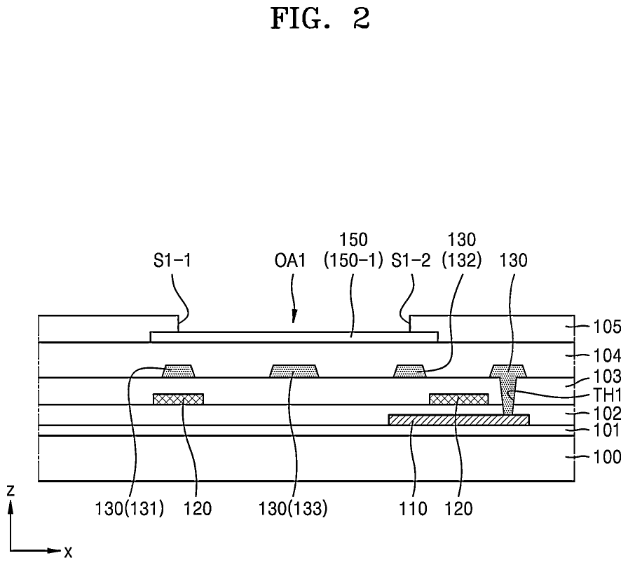

FIG. 2 is a schematic cross-sectional view of a portion of a display device according to an embodiment.

As shown in FIG. 2, the display device according to the present embodiment may include the substrate 100, a first wire 131 and a second wire 132 above the substrate 100, a planarization layer 104 covering the first wire 131 and the second wire 132, a pixel electrode 150 on the planarization layer 104, and a pixel-defining layer 105 covering the edges of the pixel electrode 150.

In addition, the display device according to the present embodiment may include a buffer layer 101, a semiconductor layer 110 on the buffer layer 101, a gate insulating layer 102 on the semiconductor layer 110, a gate layer 120 on the gate insulating layer 102, an interlayer insulating layer 103 on the gate layer 120, and a conductive layer 130 on the interlayer insulating layer 103 and forming the wiring which is under and/or connected to the pixel electrode.

As described above, the substrate 100 may include areas corresponding to the display area DA and the peripheral area PA which is adjacent to or outside the display area DA. The substrate 100 may include various materials having flexible or bendable characteristics. For example, the substrate 100 may include glass, metal, or polymer resin. In addition, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may be variously modified, for example, to have a multi-layer structure including two layers each including the above polymer resin and a barrier layer between the two layers and including an inorganic material (e.g., silicon oxide, silicon nitride, silicon oxynitride, etc.).

The buffer layer 101 may be on the substrate 100. The buffer layer 101 may serve as a barrier layer and/or a blocking layer for preventing diffusion of impurity ions, preventing penetration of moisture or external air to elements on the buffer layer 101, and planarizing a surface of the substrate 100. The buffer layer 101 may include silicon oxide, silicon nitride, or silicon oxynitride. In addition, the buffer layer 101 may adjust a rate at which heat is provided, during a crystallization process for forming (or providing) the semiconductor layer 110, thereby uniformly crystallizing the semiconductor layer 110.

The semiconductor layer 110 may be on the buffer layer 101. The semiconductor layer 110 may be formed of polysilicon and may include a channel region not doped with impurities and a source region and a drain region on both sides of the channel region and formed by doping with impurities. In this regard, impurities vary depending on types of thin-film transistors and may be N-type impurities or P-type impurities. The semiconductor layer 110 may be a semiconductor pattern within a semiconductor material layer on the substrate 100.

The gate insulating layer 102 may be on the semiconductor layer 110. The gate insulating layer 102 may be an element for securing insulation (e.g., electrical and/or thermal insulation) between the semiconductor layer 110 and the gate layer 120. The gate insulating layer 102 may include an inorganic material, such as silicon oxide, silicon nitride and/or silicon oxynitride, and may be between the semiconductor layer 110 and the gate layer 120. In addition, the gate insulating layer 102 may have a formation corresponding to the entire surface of the substrate 100 (e.g., may be disposed on an entirety of the substrate 100) and may have a structure in which contact holes are formed or provided in previously set portions. Such an insulating layer including an inorganic material may be formed through chemical vapor deposition (CVD) or atomic layer deposition (ALD). The same goes for embodiments described below and modifications thereof.

The gate layer 120 may be on the gate insulating layer 102. The gate layer 120 may be arranged at a position vertically overlapping the semiconductor layer 110 and may include at least one of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu). A detailed description of the gate layer 120 will be given later.

The interlayer insulating layer 103 may be on the gate layer 120. The interlayer insulating layer 103 may cover the gate layer 120. The interlayer insulating layer 103 may be formed of or include an inorganic material. For example, the interlayer insulating layer 103 may include metal oxide or metal nitride, and more specifically, the inorganic material may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZrO₂). In some embodiments, the interlayer insulating layer 103 may have a dual structure of SiOx/SiNy or SiNx/SiOy.

The conductive layer 130 may be on the interlayer insulating layer 103. The conductive layer 130 may overlap the gate layer 120 with the interlayer insulating layer 103 therebetween and may serve as a portion of capacitor for driving a display of an image.

The conductive layer 130 may include one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the conductive layer 130 may include a Ti layer, an Al layer and/or a Cu layer.

The conductive layer 130 is an element or material layer for forming the wiring and may include a plurality of wires 131, 132, and 133 as a plurality of wire portions or wire patterns. Each of the plurality of wires 131, 132, and 133 may be connected to the data line DL, the driving voltage line PL, etc. The data line DL and the driving voltage line PL may be configured to transmit electrical signals to the pixel PX through the plurality of wires 131, 132, and 133. That is, electrical signals from the pixel circuit which may include the data line DL, the driving voltage line PL, etc., may be variously transmitted to the pixel PX through the plurality of wires 131, 132, and 133.

The plurality of wires 131, 132, and 133 may include the first wire 131 disposed over the substrate 100 or on the interlayer insulating layer 103 and extending in the first direction. In addition, the plurality of wires 131, 132, and 133 may include the second wire 132 disposed above the substrate 100 or on the interlayer insulating layer 103, extending in the first direction, apart from the first wire 131, and having the same layer structure as the first wire 131. In addition, the plurality of wires 131, 132, and 133 may further include a first voltage line 133 disposed above the substrate 100 or on the interlayer insulating layer 103, extending in the first direction, located between the first wire 131 and the second wire 132 in a direction along the substrate 100, spaced apart from the first wire 131 and the second wire 132, and having the same layer structure as the first wire 131 and the second wire 132. As having a same layer structure, elements may be considered as being in a same layer as each other, elements may be formed in a same process and/or as including a same material as each other, elements may be respective portions of a same material layer, elements may be on a same layer by forming an interface with a same underlying or overlying layer, etc., without being limited thereto.

The planarization layer 104 may be on the conductive layer 130. In other words, the planarization layer 104 may cover the first wire 131 and the second wire 132. The planarization layer 104 may be an organic insulating layer that has a substantially flat top surface while covering the top of the conductive layer 130 and thus serves as a planarization layer. The planarization layer 104 may include, for example, an organic material, such as acryl, benzocyclobutene (BCB), or hexamethyldisiloxane (HMDSO). The planarization layer 104 may be variously modified, for example, to have a single-layer or multi-layer structure.

The pixel electrode 150 may be on the planarization layer 104. The pixel electrode 150 may be connected to the conductive layer 130 through a contact hole formed in the planarization layer 104. A display element may be on the pixel electrode 150. An OLED may be used as the display element. That is, the OLED may be interposed on, for example, the pixel electrode 150. The pixel electrode 150 may include a transmissive conductive layer formed of transmissive conductive oxide, such as ITO, In₂O₃, or IZO, and a reflective layer formed of metal, such as Al or Ag. For example, the pixel electrode 150 may have a three-layer structure of ITO/Ag/ITO.

The pixel electrode 150 may be provided in plural including a plurality of pixel electrodes. In this case, the plurality of pixel electrodes may include first to fourth pixel electrodes as described below. In addition, the pixel electrode 150 may further include additional pixel electrodes not shown. Hereinafter, detailed descriptions of the drawings will be given based on a first pixel electrode 150-1 as one pixel. The following description based on the first pixel electrode 150-1 is for convenience of description, and the same may be applied to other pixel electrodes.

The pixel-defining layer 105 may be on the planarization layer 104 and may be disposed so as to cover or overlap the edges of the first pixel electrode 150-1. That is, the pixel-defining layer 105 may cover the edges of the first pixel electrode 150-1. The pixel-defining layer 105 may have or define an opening corresponding to the pixel PX, and may define a light emission area of the pixel PX. The opening defined in the pixel-defining layer 105 may be formed or provided to expose at least a central portion of the first pixel electrode 150-1 to outside the pixel-defining layer 105.

The pixel-defining layer 105 may include an organic material, for example, polyimide or HMDSO. In addition, a spacer (not shown) may be disposed on the pixel-defining layer 105.

In an embodiment, the pixel-defining layer 105 may include a light-blocking material and may be provided to have a black color. The light-blocking material may include carbon black, carbon nanotubes, resin or paste including black dye, metal particles, for example, nickel, aluminum, molybdenum, and alloys thereof, metal oxide particles (e.g., chromium oxide), or metal nitride particles (e.g., chromium nitride). When the pixel-defining layer 105 includes a light-blocking material, the reflection of external light by metal structures disposed under the pixel-defining layer 105 may be reduced.

The pixel-defining layer 105 may have or define a first pixel opening OA1 exposing a central portion of the first pixel electrode 150-1 to outside the pixel-defining layer 105, and may be disposed on the planarization layer 104 to cover the edges of the first pixel electrode 150-1. The portion of the first pixel electrode 150-1 which is exposed to outside the pixel-defining layer 105 may define an exposed portion of the pixel electrode 150. When viewed from a direction vertical to the substrate 100 (e.g., a plan view along the direction z), the pixel-defining layer 105 may include a 1-1 edge S1-1 extending in the first direction among sidewalls or edges of the pixel-defining layer 105 which define the first pixel opening OA1, and a 1-2 edge S1-2 which is spaced apart from the 1-1 edge S1-1 with the first pixel opening OA1 therebetween.

In this regard, when viewed from a direction vertical to the substrate 100, the 1-1 edge S1-1 of the pixel-defining layer 105 may vertically overlap the first wire 131. Likewise, when viewed from a direction vertical to the substrate 100, the 1-2 edge S1-2 may vertically overlap the second wire 132.

An intermediate layer (not shown) of the OLED located on an exposed portion of the pixel electrode 150 or the first pixel electrode 150-1 which is not covered by the pixel-defining layer 105, may include a low-molecular weight material or a polymer material. A portion of the intermediate layer (not shown) may be on the pixel-defining layer 105 as well as on the first pixel electrode 150-1. In an embodiment, the intermediate layer may be on the pixel electrode 150 in the first pixel opening OA1 and extend outside of the first pixel opening OA1 to be on a side surface and an upper surface of the pixel-defining layer 105. The side surface may correspond to the 1-1 edge S1-1 and the 1-2 edge S1-2, and extend along a x-z plane. The upper surface may be a surface which is furthest from the substrate 100, without being limited thereto.

When the intermediate layer (not shown) includes a low-molecular weight material, the intermediate layer (not shown) may include a hole injection layer (HIL), a hole transport layer (HTL), an emission layer (EML), an electron transport layer (ETL) and/or an electron injection layer (EIL). When the intermediate layer (not shown) includes a polymer material, the intermediate layer (not shown) may have a structure including an HTL and an EML. Such layers may be formed by deposition, inkjet printing, screen printing, laser induced thermal imaging (LITI), or the like.

However, the intermediate layer (not shown) is not limited thereto and may have any of various other structures. In addition, the intermediate layer (not shown) may include a single layer that commonly covers a plurality of pixel electrodes 150 or may include patterned layers of an intermediate material layer respectively corresponding to the plurality of pixel electrodes 150.

An opposite electrode (not shown) may be arranged in the display area DA. That is, the opposite electrode (not shown) may be formed as a single electrode for a plurality of OLEDs to correspond to the plurality of pixel electrodes 150. The opposite electrode (not shown) may include a light-transmissive conductive layer formed of ITO, In₂O₃, or IZO and may include a semi-transmissive layer including metal, such as Al or Ag. For example, the opposite electrode (not shown) may include a semi-transmissive layer including MgAg. The opposite electrode (not shown) may face a respective pixel electrode with a portion of the intermediate layer (not shown) therebetween, for defining a light-emitting element including the anode together with the cathode and the intermediate layer (not shown).

Since the OLED may be easily damaged by external moisture or oxygen, an encapsulation layer (not shown) may cover and protect the OLED. The encapsulation layer (not shown) may cover the display area DA and extend out of the display area DA, such as into the non-display area. The encapsulation layer (not shown) may face the substrate 100 with the light-emitting element therebetween. A plurality of light-emitting elements may define a light-emitting element layer which is connected to a pixel circuit layer.

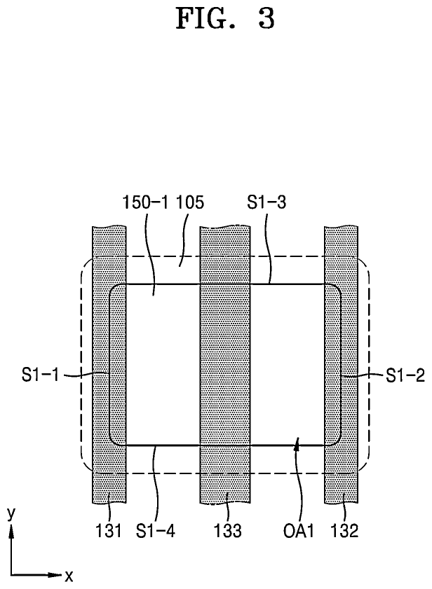

FIG. 3 is a schematic plan view of the vicinity of a pixel opening in the display device of FIG. 1.

As shown in FIG. 3, the pixel-defining layer 105 may have the first pixel opening OA1 exposing a central portion of the first pixel electrode 150-1, and may be disposed on the planarization layer 104 to cover the edges of the first pixel electrode 150-1. When viewed from a direction vertical to the substrate 100, the pixel-defining layer 105 may include the 1-1 edge S1-1 extending in the first direction among edges of the first pixel opening OA1 which define the pixel opening, and the 1-2 edge S1-2 apart from the 1-1 edge S1-1 (e.g., spaced apart from the 101 edge S1-1 along the second direction). An edge of the pixel electrode 150 may be indicated by the dotted line in FIG. 3.

In addition, the pixel-defining layer 105 may include a 1-3 edge S1-3 extending in the second direction among edges of the first pixel opening OA1 and a 1-4 edge S1-4 apart from the 1-3 edge S1-3 along the first direction. A plurality of first edges include the 1-1 edge S1-1, the 1-2 edge S1-2, the 1-3 edge S1-3 and the 1-4 edge S1-4 which define the first pixel opening OA1. The 1-3 edge S1-3 and the 1-4 edge S1-4 extend to overlap more than one wire within the wiring. The edge portions of the pixel-defining layer 105 along the 1-3 edge S1-3 and the 1-4 edge S1-4 may include an overlapping portion (e.g., at the various wires of the wiring) and a non-overlapping portion which is between the various wires along the second direction. Various elements such as the edges which extend in a direction, have a major dimension which is extended in the direction to define an extension direction of the elements.

When viewed from a direction vertical to the substrate 100, the 1-1 edge S1-1 of the pixel-defining layer 105 may vertically overlap the first wire 131. Likewise, when viewed from a direction vertical to the substrate 100, the 1-2 edge S1-2 may vertically overlap the second wire 132.

As described above, when the wiring is located under the edges of the pixel-defining layer 105 among the edges of the pixel-defining layer 105, a reflow phenomenon due to heat generated during a process for forming the pixel-defining layer 105 may be prevented or reduced. The reflow phenomenon may refer to a phenomenon in which a material constituting or forming the pixel-defining layer 105 is melted by heat. Compared to a general pixel-defining layer 105, the pixel-defining layer 105 including the above light-blocking material may be more affected by the reflow phenomenon.

More specifically, when heat is generated by heating during a process for forming the pixel-defining layer 105, the generated heat may cause the reflow phenomenon at the edges of the pixel-defining layer 105. In this regard, the generated heat may be quickly transferred along the wiring under the pixel-defining layer 105 and be released.

When a first region having the wiring under the edges of the pixel-defining layer 105, and a second region without the wiring thereunder, are alternately arranged, heat in the first region may be quickly released, whereas heat in the second region may be released slowly. As a result, a difference between respective degrees of distribution of the first region and the second region may occur. Accordingly, a problem in which a boundary surface of the first region and a boundary surface of the second region are misaligned may occur. In this regard, the boundary surface of the first region or the boundary surface of the second region may refer to a boundary surface between the first region or the second region of a pixel-defining layer 105 and a pixel electrode 150 when viewed from a vertical direction of a substrate 100.

As an example, among the edges of the pixel-defining layer 105, the first region overlapping the wiring may dissipate heat relatively quickly, so that the reflow phenomenon may be prevented or reduced. Thus, the edge of a mask pattern and the boundary surface of the first region may substantially coincide when viewed from a vertical direction of the substrate 100.

On the other hand, among the edges of the pixel-defining layer 105, the second region not overlapping the wiring from above may not dissipate heat relatively quickly, so that the reflow phenomenon occurs evenly. Thus, the edge of a mask pattern and the boundary surface of the second region may not substantially coincide when viewed from a vertical direction of the substrate 100. As used herein, element which do not overlap or are non-overlapping may be adjacent to each other along the plane and/or spaced apart from each other along the plane.

As a result of such a mismatch between the boundary surface of the first region and the boundary surface of the second region, the edges of the pixel-defining layer 105 at the place where the first region and the second region meet each other have an uneven shape. As described above, when a difference in the degree of distribution of the pixel-defining layer 105 is greater than a critical value, the corresponding display panel 10 may be determined to be defective.

Accordingly, during a process for forming the pixel-defining layer 105, depending on how the wiring is arranged under the edges of the pixel-defining layer 105 which define a respective pixel opening, the reflow phenomenon occurring at the edges of the pixel-defining layer 105 may be controlled. Thus, a difference in the degree of distribution of material which forms the pixel-defining layer 105 may be reduced.

Accordingly, a region in which a difference in the degree of distribution occurs in the pixel-defining layer 105 of the corresponding display panel 10 may be reduced since the 1-1 edge S1-1 vertically overlaps the first wire 131 and the 1-2 edge S1-2 vertically overlaps the second wire 132. That is, the reflow phenomenon occurring at the 1-1 edge S1-1 or the 1-2 edge S1-2 which extend along the various wires under the edges may be prevented or reduced. That is, the various edges of the pixel-defining layer 105 may extend in the extension direction of the corresponding wires within the wiring.

However, a difference in the degree of distribution may occur at the 1-3 edge S1-3 and the 1-4 edge S1-4 described above and at corner regions of the first pixel opening OA1 adjacent to the 1-1 edge S1-1 and the 1-2 edge S1-2, but a difference in the degree of distribution may be reduced in other regions. A corner or corner region of a respective pixel opening may be defined by edges of the pixel-defining layer 105 which meet each other.

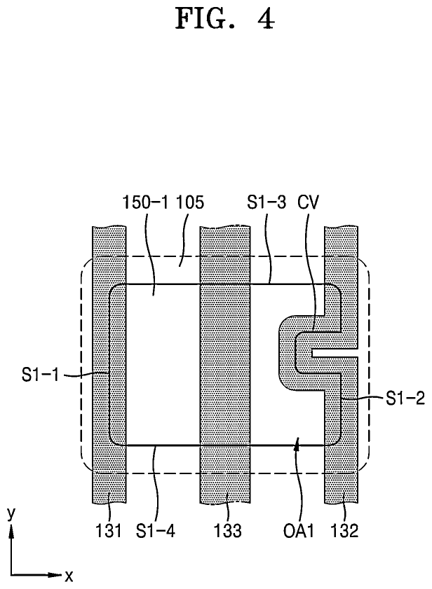

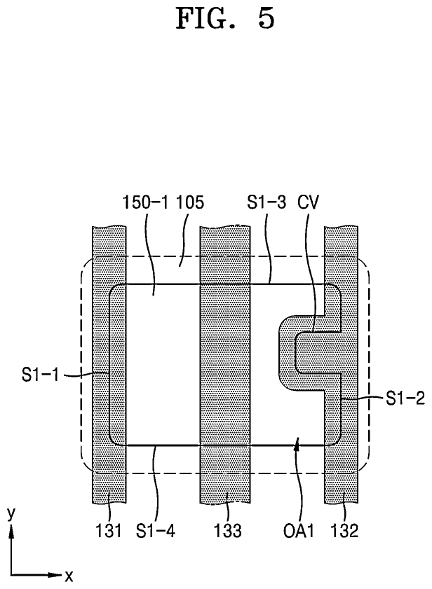

FIG. 4 is a schematic plan view of the vicinity of a pixel opening in the display device of FIG. 1. FIG. 5 is a schematic plan view of the vicinity of a pixel opening in the display device of FIG. 1.

As shown in FIG. 4, a portion of the 1-2 edge S1-2 may be recessed into the first pixel opening OA1. A protruded portion of the pixel-defining layer 105 may define the recessed portion of the 1-2 edge S1-2. In this case, a shape or edge of the second wire 132 may correspond to a recessed shape of the 1-2 edge S1-2. That is, a protruded portion of the second wire 132 may have a shape protruded into the first pixel opening OA1 according to a recessed shape CV of a portion of the 1-2 edge S1-2. A protruded portion of the second wire 132 at a first side thereof may include or define a groove recessed from a second side of the second wire 132, where the groove extends from the outside to the inside of the first pixel opening OA1. That is, one edge among the 1-1 edge S1-1 and the 1-2 edge S1-2 includes a protruded portion (e.g., the recessed shape CV) which protrudes toward the other edge among the 1-1 edge S1-1 and the 1-2 edge S1-2. The protruded portion may be further toward the other edge than a remaining portion of the one edge.

As shown in FIG. 5, a portion of the second wire 132 may have a shape recessed into the first pixel opening OA1 according to the recessed shape CV of a portion of the 1-2 edge S1-2. In this case, a shape of the second wire 132 at a first side thereof may correspond to a shape of the 1-2 edge S1-2, but a portion of the second wire 132 which corresponds to the recessed shape may not include a groove recessed in a direction from the outside to the inside of the first pixel opening OA1. That is, the second side of the second wire 132 may have a straight edge which is furthest from the pixel opening.

Unlike that shown in FIGS. 4 and 5, a portion of the 1-1 edge S1-1 may also be recessed into the first pixel opening OA1. In this case, a shape of the first wire 131 may correspond to a shape of the 1-1 edge S1-1. That is, a portion of the first wire 131 may have a shape recessed into the first pixel opening OA1 according to the recessed shape of a portion of the 1-1 edge S1-1. In addition, a portion of the first wire 131 may include a groove recessed from the outside to the inside of the first pixel opening OA1.

Accordingly, a portion of at least one of the 1-1 edge S1-1 and the 1-2 edge S1-2 may be recessed into the first pixel opening OA1. That is, one edge among the 1-1 edge S1-1 and the 1-2 edge S1-2 may include a protruded portion which protrudes toward the other edge among the 1-1 edge S1-1 and the 1-2 edge S1-2. When viewed from a direction vertical to the substrate 100, a shape of the first wire 131 may correspond to a shape of the 1-1 edge S1-1, and a shape of the second wire 132 may correspond to a shape of the 1-2 edge S1-2.

However, shapes of the first wire 131, the second wire 132, and the first voltage line 133 shown in FIGS. 4 and 5 are merely examples and are illustrated in the most simplified form for convenience of description. As an example, the first voltage line 133 may have a shape corresponding to a shape of the first pixel electrode 150-1. As described above, it is apparent from the present description that various modifications may be made according to the shape of a pixel or the position where a pixel is arranged, and this is also true for other drawings described below.

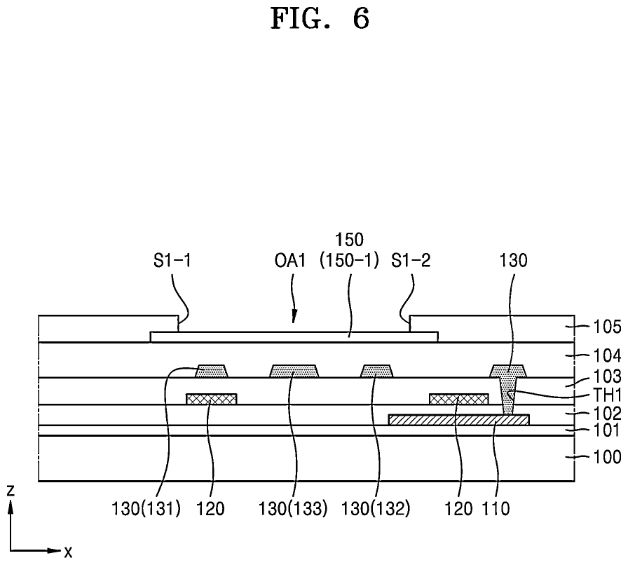

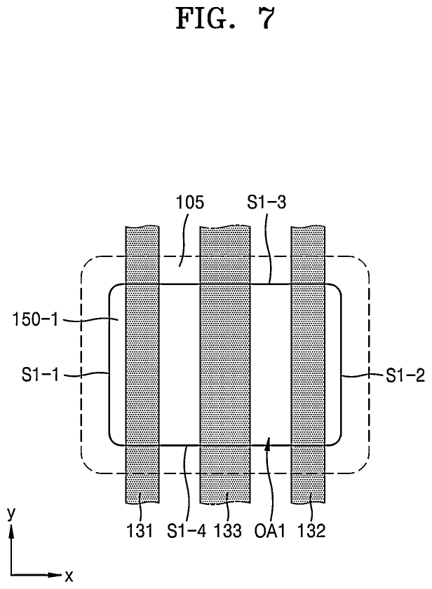

FIG. 6 is a schematic cross-sectional view of a portion of the display device of FIG. 1. FIG. 7 is a schematic plan view of the vicinity of a pixel opening in the display device of FIG. 6.

As shown in FIGS. 6 and 7, when viewed from a direction vertical to the substrate 100, the first wire 131 may be between the 1-1 edge S1-1 and the 1-2 edge S1-2 and thus may be apart from the 1-1 edge S1-1 and the 1-2 edge S1-2. That is, the wiring including the first wire 131, the first voltage line 133 and the second wire 132 in order in the second direction, is between opposing edges of the pixel-defining layer 105 which define the pixel opening along the second direction. The first wire 131 which is closest to a first edge (e.g., the 1-1 edge S1-1) and the second wire 132 which is closest to the second edge (e.g., the 1-2 edge (S1-2), are respectively spaced apart from the closest pixel opening edge.

Among the 1-3 edge S1-3 and the 1-4 edge S1-4, overlapping portions alternate with non-overlapping portions, along the second direction. In FIG. 7, for example, a non-overlapping portion among the 1-3 edge S1-3 and the 1-4 edge S1-4 meets the -1 edge S1-1 and the 1-2 edge S1-2 to define a corner portion. In FIG. 3, for example, an overlapping portion among the 1-3 edge S1-3 and the 1-4 edge S1-4 meets the -1 edge S1-1 and the 1-2 edge S1-2 to define a corner portion.

In addition, when viewed from a direction vertical to the substrate 100, the second wire 132 may be between the 1-1 edge S1-1 and the 1-2 edge S1-2 and thus may be apart from the 1-1 edge S1-1 and the 1-2 edge S1-2.

In addition, the first voltage line 133 may be between the first wire 131 and the second wire 132, and thus, the wiring overlapping the edges of the pixel-defining layer 105 may be reduced.

As described above, when heat is generated by heating during a process for forming the pixel-defining layer 105, the generated heat may cause the reflow phenomenon at the edges of the pixel-defining layer 105. Since the first wire 131 and the second wire 132 do not overlap the 1-1 edge S1-1 and the 1-2 edge S1-2 from below as shown in FIGS. 6 and 7, the generated heat may be evenly transferred throughout the 1-1 edge S1-1 and the 1-2 edge S1-2. Accordingly, the reflow phenomenon occurring at the 1-1 edge S1-1 and the 1-2 edge S1-2 may evenly occur at locations along the 1-1 edge S1-1 and the 1-2 edge S1-2.

As described above, a difference in the degree of distribution of the 1-1 edge S1-1 and the 1-2 edge S1-2 may be reduced by causing the reflow phenomenon to evenly occur at positions along the 1-1 edge S1-1 and the 1-2 edge S1-2. The reduction in a difference in the degree of distribution refers to a reduction in the degree of unevenness of the edges defining the pixel opening.

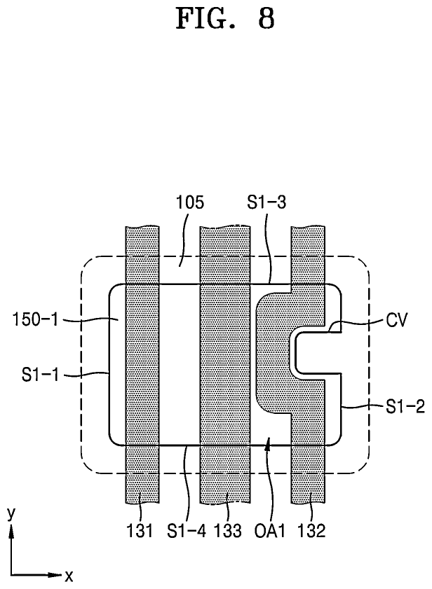

FIG. 8 is a schematic plan view of the vicinity of a pixel opening in the display device of FIG. 6.

As shown in FIG. 8, a portion of the 1-2 edge S1-2 may be recessed into the first pixel opening OA1. In this case, a shape of the second wire 132 may correspond to a shape of the 1-2 edge S1-2. That is, a portion of the second wire 132 may have a shape recessed into the first pixel opening OA1 according to the recessed shape CV of a portion of the 1-2 edge S1-2. A portion of the second wire 132 may include a groove recessed from the outside to the inside of the first pixel opening OA1.

In this regard, a recessed shape of the second wire 132 may be spaced apart from the 1-2 edge S1-2 by a certain distance so as to not overlap the 1-2 edge S1-2. That is, a portion of the second wire 132 may also be recessed from the outside to the inside of the first pixel opening OA1 but may be apart from the recessed portion of the 1-2 edge S1-2.

Unlike that shown in FIG. 8, a portion of the 1-1 edge S1-1 may also be recessed into the first pixel opening OA1. In this case, a shape of the first wire 131 may correspond to a shape of the 1-1 edge S1-1. That is, a portion of the first wire 131 may have a shape recessed into the first pixel opening OA1 according to the recessed shape of a portion of the 1-1 edge S1-1. In this regard, a shape of the first wire 131 may be spaced apart from the 1-1 edge S1-1 by a certain distance not to overlap the 1-1 edge S1-1. That is, a portion of the first wire 131 may also be recessed from the outside to the inside of the first pixel opening OA1 but may be apart from the recessed portion of the 1-1 edge S1-1.

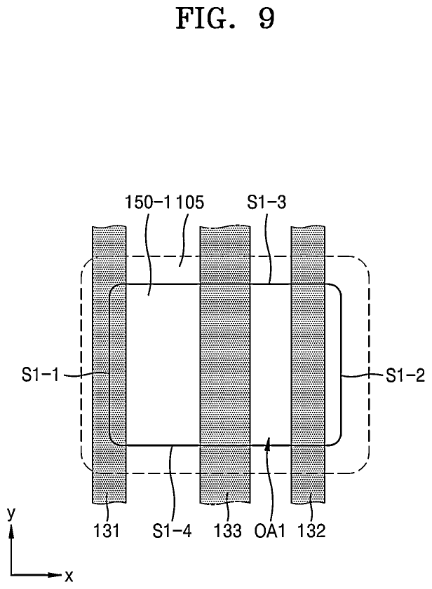

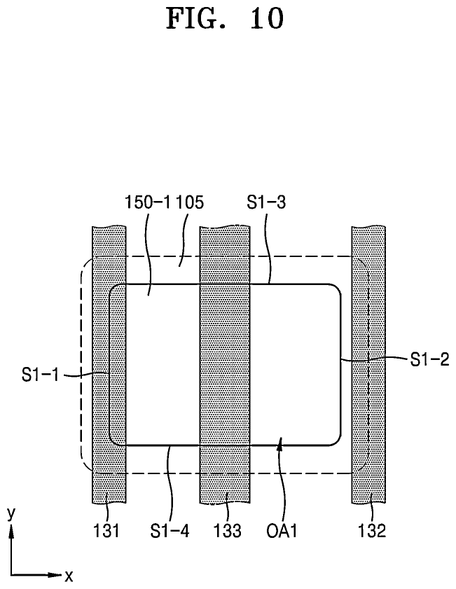

FIG. 9 is a schematic plan view of the vicinity of a pixel opening in the display device of FIG. 1. FIG. 10 is a schematic plan view of the vicinity of a pixel opening in the display device of FIG. 1.

Referring to FIGS. 9 and 10, only one edge among the 1-1 edge S1-1 and the 1-2 edge S1-2 of the pixel-defining layer 105 according to the present embodiment may vertically overlap the wiring. As an example, while the 1-1 edge S1-1 of the pixel-defining layer 105 vertically overlaps the first wire 131, the 1-2 edge S1-2 may not vertically overlap the second wire 132.

In addition, as an example, cases in which the 1-2 edge S1-2 and the second wire 132 do not overlap each other may be divided into two types. One is the case in which, as shown in FIG. 9, the second wire 132 is between the 1-1 edge S1-1 and the 1-2 edge S1-2 and is apart from the 1-2 edge S1-2. Here, the second wire 132 is inside the first pixel opening OA1. The other is the case in which, as shown in FIG. 10, the second wire 132 is located outside the first pixel opening OA1 and is apart from the 1-2 edge S1-2. That is, the 1-2 edge S1-2 is between the pixel opening and the second wire 132.

Although only the 1-2 edge S1-2 and the second wire 132 have been described for convenience, the same descriptions may be applied to the 1-1 edge S1-1 and the first wire 131. In an embodiment, for example, a plurality of edges of the pixel-defining layer 105 includes the first edge provided in plural including a plurality of first edges spaced apart along the second direction (e.g., the 1-1 edge S1-1 and the 1-2 edge S1-2), and a second edge (e.g., the 1-3 edge S1-3 or the 1-4 edge S1-4) meets the plurality of first edges at a plurality of corners of the pixel opening, the plurality of corners being opposite to each other along the second direction (e.g., left and right corners in FIG. 9). An overlapping area is defined at one corner (e.g., the left corners) among the plurality of corners of the pixel opening, and along one first edge (e.g., the 1-1 edge S1-1) among the plurality of first edges, and a non-overlapping area is further defined at another corner (e.g., the right corners) among the plurality of corners of the pixel opening, and along another first edge (e.g., the 1-2 edge S1-2) among the plurality of first edges.

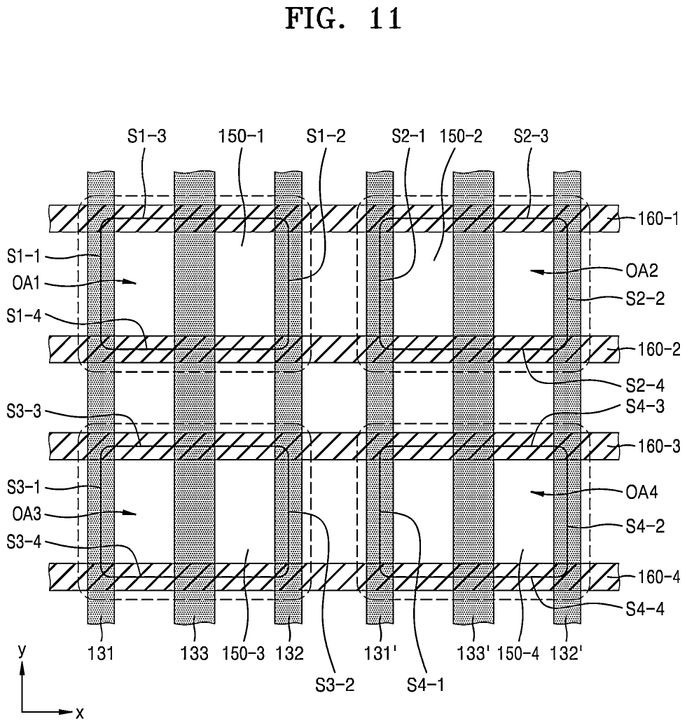

FIG. 11 is a schematic plan view of the vicinity of a plurality of pixel openings OA1, OA2, OA3, and OA4 in the display device of FIG. 1.

As shown in FIG. 11, the pixel-defining layer 105 of the display device according to the present embodiment may include or define the plurality of pixel openings OA1, OA2, OA3, and OA4. The pixel-defining layer 105 may include edges extending in (or along) the first direction and edges extending in (or along) the second direction among edges of the pixel-defining layer 105 respectively defining the plurality of pixel openings OA1, OA2, OA3, and OA4.

The plurality of pixel openings OA1, OA2, OA3, and OA4 may include the first pixel opening OA1 and a third pixel opening OA3 arranged side by side (e.g., adjacent to each other) in the first direction. A second pixel opening OA2 may be arranged side by side with the first pixel opening OA1 in the second direction. A fourth pixel opening OA4 may be arranged side by side with the second pixel opening OA2 in the first direction and may be arranged side by side with the third pixel opening OA3 in the second direction.

The display device according to the present embodiment may include a plurality of pixel electrodes 150-1, 150-2, 150-3, and 150-4 of a pixel electrode layer which respectively correspond to the plurality of pixel openings OA1, OA2, OA3, and OA4. Referring to FIG. 11, the display device may include the first pixel electrode 150-1 corresponding to the first pixel opening OA1, a second pixel electrode 150-2 corresponding to the second pixel opening OA2, a third pixel electrode 150-3 corresponding to the third pixel opening OA3, and a fourth pixel electrode 150-4 corresponding to the fourth pixel opening OA4. The first pixel electrode 150-1 and the third pixel electrode 150-3 may share the first wire 131 and the second wire 132. In addition, the second pixel electrode 150-2 and the fourth pixel electrode 150-4 may share a third wire 131′ and a fourth wire 132′. As sharing an element, wires may commonly overlap such element, may be commonly connected to such element, etc.

In addition, the first pixel electrode 150-1 and the second pixel electrode 150-2 may share a fifth wire 160-1 and a sixth wire 160-2 described below. In addition, the third pixel electrode 150-3 and the fourth pixel electrode 150-4 may share a seventh wire 160-3 and an eighth wire 160-4 described below. The first to seventh wires may be wire portions within the wiring described above, without being limited thereto.

As an example, the first to fourth wires 131 to 132′ may be the data line DL or wires connected to the data line DL, and the fifth to eighth wires 160-1 to 160-4 may be the scan line SL or wires connected to the scan line SL. The first to fourth wires 131 to 132′ may respectively be wire patterns of a first wiring layer. The first to fourth wires 131 to 132′ are in order along the second direction and spaced apart from each other along the second. The fifth to eighth wires 160-1 to 160-4 may respectively be wire patterns of a second wiring layer. In addition, the first voltage line 133 and a second voltage line 133′ may be the driving voltage line PL described above or wires connected to the driving voltage line PL. The first voltage line 133 and a second voltage line 133′ may respectively be wire patterns of the second wiring layer.

The display device according to the present embodiment may include the first wire 131 and the second wire 132 described above and may further include the third wire 131′ and the fourth wire 132′. In addition, the display device according to the present embodiment may further include additional wires not shown, and in the present description, only some wires are mainly described for convenience.

The third wire 131′ may be disposed above the substrate 100, may extend in the first direction, and may be apart from the second wire 132 and opposite to the first wire 131 with respect to the second wire 132. In addition, the third wire 131′ may have the same layer structure as the first wire 131. The third wire 131′ may include the same material as the first wire 131. In an embodiment, the third wire 131′ may be in a same layer as the first wire 131, without being limited thereto.

The fourth wire 132′ may be disposed above the substrate 100, may extend in the first direction, and may be apart from the third wire 131′ and opposite to the first wire 131 with respect to the third wire 131′. In addition, the fourth wire 132′ may have the same layer structure as the first wire 131. The fourth wire 132′ may include the same material as the first wire 131. In an embodiment, the fourth wire 132′ may be in the same layer as the first wire 131, without being limited thereto Accordingly, the planarization layer 104 may cover not only the first wire 131 and the second wire 132 but also the third wire 131′ and the fourth wire 132′, where the first wire 131, the second wire 132, the third wire 131′ and the fourth wire 132′ are respective portions of a same layer (e.g., the conductive layer 130).

The pixel-defining layer 105 may have the first pixel opening OA1 exposing a central portion of the first pixel electrode 150-1. The pixel-defining layer 105 may be disposed on the planarization layer 104 to cover the edges of the first pixel electrode 150-1. That is, the first pixel electrode 150-1 may be on the planarization layer 104.

The pixel-defining layer 105 may include the 1-1 edge S1-1 extending in the first direction among edges of the first pixel opening OA1 when viewed from a direction vertical to the substrate 100, and the 1-2 edge S1-2 extending in the first direction and apart from the 1-1 edge S1-1 among edges of the first pixel opening OA1 when viewed from a direction vertical to the substrate 100. In this regard, the 1-1 edge S1-1 may overlap the first wire 131, and the 1-2 edge S1-2 may overlap the second wire 132.

The pixel-defining layer 105 may include the 1-3 edge S1-3 extending in the second direction among edges of the first pixel opening OA1 when viewed from a direction vertical to the substrate 100, and the 1-4 edge S1-4 extending in the second direction and apart from the 1-3 edge S1-3 among edges of the first pixel opening OA1 when viewed from a direction vertical to the substrate 100. In this regard, the 1-3 edge S1-3 may overlap the fifth wire 160-1, and the 1-4 edge S1-4 may overlap the sixth wire 160-2.

The pixel-defining layer 105 may have the second pixel opening OA2 exposing a central portion of the second pixel electrode 150-2. The pixel-defining layer 105 may be disposed on the planarization layer 104 to cover the edges of the second pixel electrode 150-2. That is, the second pixel electrode 150-2 may be on the planarization layer 104 and may be apart from the first pixel electrode 150-1 in the second direction.

The pixel-defining layer 105 may include a 2-1 edge S2-1 extending in the first direction among edges of the second pixel opening OA2 when viewed from a direction vertical to the substrate 100, and a 2-2 edge S2-2 extending in the first direction and apart from the 2-1 edge S2-1 among edges of the second pixel opening OA2 when viewed from a direction vertical to the substrate 100. In this regard, the 2-1 edge S2-1 may overlap the third wire 131′, and the 2-2 edge S2-2 may overlap the fourth wire 132′.

The pixel-defining layer 105 may include a 2-3 edge S2-3 extending in the second direction among edges of the second pixel opening OA2 when viewed from a direction vertical to the substrate 100, and a 2-4 edge S2-4 extending in the second direction and apart from the 2-3 edge S2-3 among edges of the second pixel opening OA2 when viewed from a direction vertical to the substrate 100. A plurality of second edges include the 2-1 edge S2-1, the 2-2 edge S2-2, the 2-3 edge S2-3 and the 2-4 edge S2-4 which define the second pixel opening OA2. In this regard, the 2-3 edge S2-3 may overlap the fifth wire 160-1, and the 2-4 edge S2-4 may overlap the sixth wire 160-2.

The pixel-defining layer 105 may have the third pixel opening OA3 exposing a central portion of the third pixel electrode 150-3. The pixel-defining layer 105 may be disposed on the planarization layer 104 to cover the edges of the third pixel electrode 150-3. That is, the third pixel electrode 150-3 may be on the planarization layer 104 and may be apart from the first pixel electrode 150-1 in the first direction.

The pixel-defining layer 105 may include a 3-1 edge S3-1 extending in the first direction among edges of the third pixel opening OA3 when viewed from a direction vertical to the substrate 100, and a 3-2 edge S3-2 extending in the first direction and apart from the 3-1 edge S3-1 among edges of the third pixel opening OA3 when viewed from a direction vertical to the substrate 100. In this regard, the 3-1 edge S3-1 may overlap the first wire 131, and the 3-2 edge S3-2 may overlap the second wire 132.

The pixel-defining layer 105 may include a 3-3 edge S3-3 extending in the second direction among edges of the third pixel opening OA3 when viewed from a direction vertical to the substrate 100, and a 3-4 edge S3-4 extending in the second direction and apart from the 3-3 edge S3-3 among edges of the third pixel opening OA3 when viewed from a direction vertical to the substrate 100. A plurality of third edges include the 3-1 edge S3-1, the 3-2 edge S3-2, the 3-3 edge S3-3 and the 3-4 edge S3-4 which define the third pixel opening OA3. In this regard, the 3-3 edge S3-3 may overlap the seventh wire 160-3, and the 3-4 edge S3-4 may overlap the eighth wire 160-4.

The pixel-defining layer 105 may have the fourth pixel opening OA4 exposing a central portion of the fourth pixel electrode 150-4. The pixel-defining layer 105 may be disposed on the planarization layer 104 to cover the edges of the fourth pixel electrode 150-4. That is, the fourth pixel electrode 150-4 may be on the planarization layer 104 and may be apart from the second pixel electrode 150-2 in the first direction.

The pixel-defining layer 105 may include a 4-1 edge S4-1 extending in the first direction among edges of the fourth pixel opening OA4 when viewed from a direction vertical to the substrate 100, and a 4-2 edge S4-2 extending in the first direction and apart from the 4-1 edge S4-1 among edges of the fourth pixel opening OA4 when viewed from a direction vertical to the substrate 100. In this regard, the 4-1 edge S4-1 may overlap the third wire 131′, and the 4-2 edge S4-2 may overlap the fourth wire 132′.

The pixel-defining layer 105 may include a 4-3 edge S4-3 extending in the second direction among edges of the fourth pixel opening OA4 when viewed from a direction vertical to the substrate 100, and a 4-4 edge S4-4 extending in the second direction and apart from the 4-3 edge S4-3 among edges of the fourth pixel opening OA4 when viewed from a direction vertical to the substrate 100. A plurality of fourth edges include the 4-1 edge S4-1, the 4-2 edge S4-2, the 4-3 edge S4-3 and the 4-4 edge S4-4 which define the fourth pixel opening OA4. In this regard, the 4-3 edge S4-3 may overlap the seventh wire 160-3, and the 4-4 edge S4-4 may overlap the eighth wire 160-4.

For reference, the first voltage line 133 extending in the first direction may be arranged between the first wire 131 and the second wire 132. In addition, the second voltage line 133′ extending in the first direction may be arranged between the third wire 131′ and the fourth wire 132′, and the second voltage line 133′ may include the same material and have the same layer structure as the first voltage line 133 described above.

For reference, although the wires shown in FIG. 11 are illustrated as straight lines for convenience of description, this should not limit the scope as defined by the appended claims. The wires described herein may be modified in various forms. Referring to the various embodiments described above, the wiring may or may not overlap the edges of the pixel-defining layer 105 to control a reflow phenomenon depending on whether to overlap the edges of the pixel-defining layer 105 or not.

For reference, descriptions of the wiring shown in FIG. 11 may be replaced with the above descriptions of FIGS. 4 to 10. As an example, in the case of an edge including a recessed region, a wire corresponding to the recessed region may be arranged, and this may be apparently derived from the entirety of this specification.

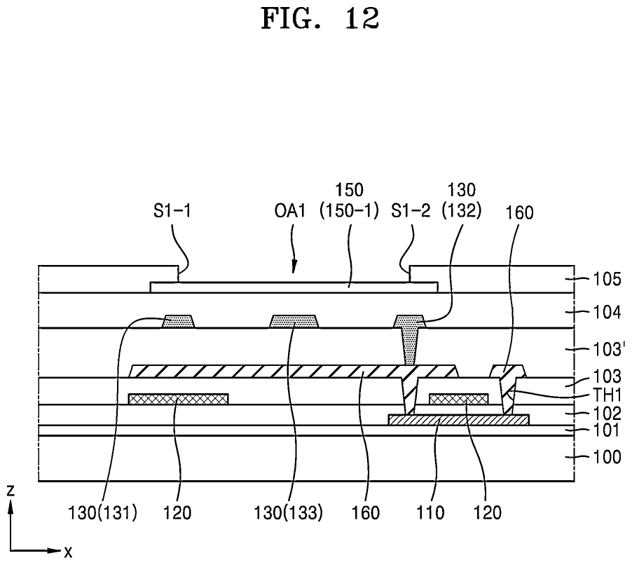

FIG. 12 is a schematic cross-sectional view of a portion of a display device according to the present embodiment.

As shown in FIG. 12, the display device may include the substrate 100, the buffer layer 101 on the substrate 100, the semiconductor layer 110 on the buffer layer 101, the gate insulating layer 102 covering the semiconductor layer 110, the gate layer 120 on the gate insulating layer 102, the interlayer insulating layer 103 covering the gate layer 120, a first conductive layer 160 on the interlayer insulating layer 103, an organic insulating layer 103′ on the first conductive layer 160, a second conductive layer 130 on the organic insulating layer 103′, and the planarization layer 104 on the second conductive layer 130. The display device may include the pixel electrode 150 on the planarization layer 104 and the pixel-defining layer 105 covering the edges of the pixel electrode 150.

In this regard, descriptions of the substrate 100, the semiconductor layer 110, the gate insulating layer 102, the gate layer 120, and the interlayer insulating layer 103 are the same as or overlap the above descriptions of FIGS. 2 to 11 and thus may be omitted.

The first conductive layer 160 may be under the second conductive layer 130 described below and may be above the interlayer insulating layer 103. That is, the first conductive layer 160 and the second conductive layer 130 may be in different layers from each other. The first conductive layer 160 may overlap the gate layer 120 with the interlayer insulating layer 103 therebetween and serve as a portion of a capacitor for driving a display.

The first conductive layer 160 may include the same material as the conductive layer described above. The first conductive layer 160 may have the same layer structure as the conductive layer described above. The first conductive layer 160 may include the scan line SL described above or wires connected to the scan line SL. That is, the first conductive layer 160 may include wires extending in the second direction, such as the fifth wire 160-1, the sixth wire 160-2, the seventh wire 160-3, and the eighth wire 160-4 described above.

The first conductive layer 160 may include one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first conductive layer 160 may include a Ti layer, an Al layer and/or a Cu layer.

The organic insulating layer 103′ may be an organic insulating layer that has a substantially flat top surface while covering the top of the first conductive layer 160 and thus serves as a planarization layer. The organic insulating layer 103′ may include, for example, an organic material, such as acryl, BCB, or HMDSO. The organic insulating layer 103′ may be variously modified, for example, to have a single-layer or multi-layer structure.

The second conductive layer 130 may be under the pixel electrode 150 and may be on the organic insulating layer 103′. The second conductive layer 130 may perform the same role as the conductive layer 130 described above with reference to FIG. 2, etc. Accordingly, the second conductive layer 130 may include patterns which provide the first wire 131 and the second wire 132. In addition, when the plurality of pixel openings OA1, OA2, OA3, and OA4 are arranged, the second conductive layer 130 may further include patterns which provide the third wire 131′ and the fourth wire 132′. In addition, the second conductive layer 130 may further include patterns which provide the first voltage line 133 and the second voltage line 133′. The second conductive layer 130 may be connected to the data line DL or a power line ELVDD. In an embodiment, the second conductive layer 130 may include the data line DL described above or wires connected to the data line DL. In addition, the second conductive layer 130 above the substrate 100 may be covered by the planarization layer 104.

The second conductive layer 130 may include one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the second conductive layer 130 may include a Ti layer, an Al layer and/or a Cu layer.

The planarization layer 104 may perform the same role as the planarization layer described above with reference to FIG. 2, etc. The planarization layer 104 may be an organic insulating layer that has a substantially flat top surface while covering the top of the second conductive layer 130 and thus serves as a planarization layer. The planarization layer 104 may include, for example, an organic material, such as acryl, BCB, or HMDSO. The planarization layer 104 may be variously modified, for example, to have a single-layer or multi-layer structure.

The pixel electrode 150 may be on the planarization layer 104 and may be an element patterned into a previously set shape. A description of the pixel electrode 150 is the same as or overlaps the above description and thus may be omitted.

On the planarization layer 104, the pixel-defining layer 105 may cover the edges of the first pixel electrode 150-1. The pixel-defining layer 105 may have the first pixel opening OA1 exposing a central portion of the first pixel electrode 150-1 and may be disposed on the planarization layer 104 to cover the edges of the first pixel electrode 150-1. Descriptions of other elements on the pixel-defining layer 105 and the first pixel electrode 150-1 are the same as or overlap the above descriptions and thus may be omitted.

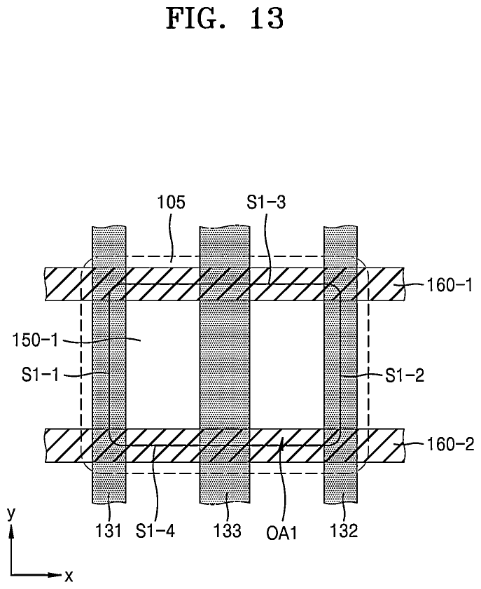

FIG. 13 is a schematic plan view of the vicinity of a pixel opening in the display device of FIG. 12.

When viewed from a direction vertical to the substrate 100, the pixel-defining layer 105 may include the 1-1 edge S1-1 extending in the first direction among edges of the first pixel opening OA1 and the 1-2 edge S1-2 apart from the 1-1 edge S1-1. In addition, the pixel-defining layer 105 may include the 1-3 edge S1-3 extending in the second direction among edges of the first pixel opening OA1 and the 1-4 edge S1-4 apart from the 1-3 edge S1-3.

In this regard, when viewed from a direction vertical to the substrate 100, the 1-1 edge S1-1 of the pixel-defining layer 105 may vertically overlap the first wire 131. Likewise, when viewed from a direction vertical to the substrate 100, the 1-2 edge S1-2 may vertically overlap the second wire 132.

The reflow phenomenon occurring at the 1-1 edge S1-1 and the 1-2 edge S1-2 may be prevented or reduced since the 1-1 edge S1-1 vertically overlaps the first wire 131 and the 1-2 edge S1-2 vertically overlaps the second wire 132.

In this regard, when viewed from a direction vertical to the substrate 100, the 1-3 edge S1-3 of the pixel-defining layer 105 may vertically overlap the fifth wire 160-1. Likewise, when viewed from a direction vertical to the substrate 100, the 1-4 edge S1-4 may vertically overlap the sixth wire 160-2.

The reflow phenomenon occurring at the 1-3 edge S1-3 and the 1-4 edge S1-4 may be prevented or reduced since the 1-3 edge S1-3 vertically overlaps the fifth wire 160-1 and the 1-4 edge S1-4 vertically overlaps the sixth wire 160-2.

Distances between layers or patterns may be defined along the thickness direction (e.g., the third direction or direction z). A respective distance between the fifth and sixth wires 160-1 and 160-2, and the pixel-defining layer 105, in a direction vertical from the top of a substrate 100, may be greater than a respective distance between the above-described first to fourth wires 131 to 132′, and the pixel-defining layer 105, in a direction vertical from the top of the substrate 100. That is, the first conductive layer 160 is closer to the pixel-defining layer 105 than the second conductive layer 130. Accordingly, influence of the fifth and sixth wires 160-1 and 160-2 on the degree of distribution of material at the edges of the pixel-defining layer 105 may be relatively less than that of the first to fourth wires 131 to 132′.

Nevertheless, when a region in which the fifth wire 160-1 overlaps the 1-3 edge S1-3 to define an overlapping area, and a region in which the fifth wire 160-1 does not overlap the 1-3 edge S1-3 to define a non-overlapping area, are alternately arranged along the 1-3 edge S1-3, the reflow phenomenon may occur at the 1-3 edge S1-3 inconsistently. As a result, a difference in the degree of distribution of material at the 1-3 edge S1-3 may increase. This may be the same for the sixth wire 160-2 and the 1-4 edge S1-4. Accordingly, positions of the fifth wire 160-1 or the sixth wire 160-2 relative to the edges of the pixel-defining layer 105 may also be carefully considered.

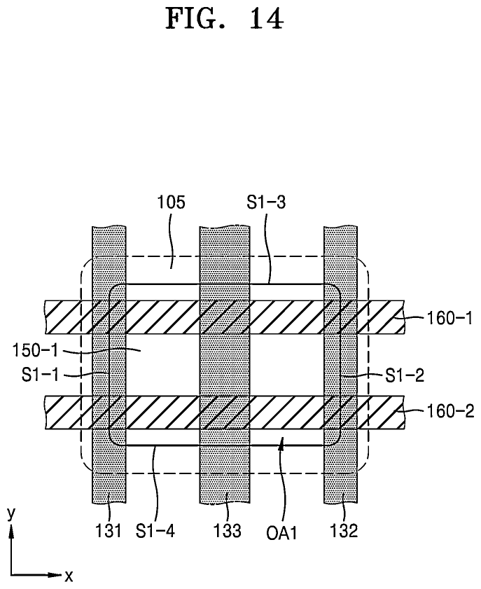

FIG. 14 is a schematic plan view of the vicinity of a pixel opening in the display device of FIG. 12.

As shown in FIG. 14, the 1-3 edge S1-3 may not vertically overlap the fifth wire 160-1 when viewed from a direction vertical to the substrate 100, and the 1-4 edge S1-4 may not vertically overlap the sixth wire 160-2 when viewed from a direction vertical to the substrate 100. Thus, the reflow phenomenon occurring at the 1-3 edge S1-3 and the 1-4 edge S1-4 may be prevented or reduced.

When viewed from a direction vertical to the substrate 100, the fifth wire 160-1 may be between the 1-3 edge S1-3 and the 1-4 edge S1-4 and thus may be apart from the 1-3 edge S1-3 and the 1-4 edge S1-4.

In addition, when viewed from a direction vertical to the substrate 100, the sixth wire 160-2 may be between the 1-3 edge S1-3 and the 1-4 edge S1-4 and thus apart from the 1-3 edge S1-3 and the 1-4 edge S1-4, and may be further apart from the fifth wire 160-1 in the first direction. That is, where the fifth and sixth wires 160-1 and 160-2 have a length in an extension direction along the second direction (e.g., direction x), a width may be defined in a normal direction relative to the extension direction. In FIG. 14, an entirety of the width of the fifth and sixth wires 160-1 and 160-2 is between the 1-3 edge S1-3 and the 1-4 edge S1-4.

In addition, the first voltage line 133 may be between the first wire 131 and the second wire 132, and thus, the wiring overlapping the edges of the pixel-defining layer 105 may be reduced.

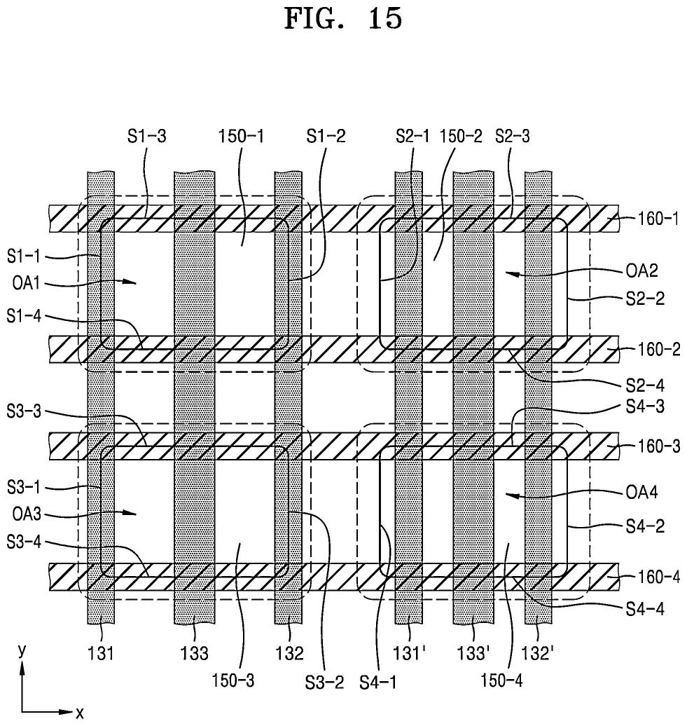

FIG. 15 is a schematic plan view of the vicinity of the plurality of pixel openings OA1, OA2, OA3, and OA4 in the display device of FIG. 1.

As shown in FIG. 15, the pixel-defining layer 105 of the display device according to the present embodiment may include the plurality of pixel openings OA1, OA2, OA3, and OA4 respectively corresponding to the plurality of pixel electrodes 150-1, 150-2, 150-3, and 150-4. The pixel-defining layer 105 may include an edge extending in the first direction and an edge extending in the second direction among edges of each of the plurality of pixel openings OA1, OA2, OA3, and OA4.

The plurality of pixel openings OA1, OA2, OA3, and OA4 may include the first pixel opening OA1 and the third pixel opening OA3 arranged side by side in the first direction. The second pixel opening OA2 may be arranged side by side with the first pixel opening OA1 in the second direction. The fourth pixel opening OA4 may be arranged side by side with the second pixel opening OA2 in the first direction and may be arranged side by side with the third pixel opening OA3 in the second direction.

Hereinafter, descriptions of the first to fourth pixel openings OA1 to OA4 are the same as or overlap those given with reference to FIG. 11 and thus may be omitted, and differences from FIG. 11 may be mainly described.

The pixel-defining layer 105 may have the first pixel opening OA1 exposing a central portion of the first pixel electrode 150-1. The pixel-defining layer 105 may be disposed on the above-described planarization layer 104 to cover the edges of the first pixel electrode 150-1. The pixel-defining layer 105 may include the 1-1 edge S1-1 extending in the first direction among edges of the first pixel opening OA1 when viewed from a direction vertical to the substrate 100, and the 1-2 edge S1-2 extending in the first direction and apart from the 1-1 edge S1-1 among edges of the first pixel opening OA1 when viewed from a direction vertical to the substrate 100. In this regard, the 1-1 edge S1-1 may overlap the first wire 131, and the 1-2 edge S1-2 may overlap the second wire 132.

The pixel-defining layer 105 may have the second pixel opening OA2 exposing a central portion of the second pixel electrode 150-2. The pixel-defining layer 105 may be disposed on the planarization layer 104 to cover the edges of the second pixel electrode 150-2. The pixel-defining layer 105 may include the 2-1 edge S2-1 extending in the first direction among edges of the second pixel opening OA2 when viewed from a direction vertical to the substrate 100, and the 2-2 edge S2-2 extending in the first direction and apart from the 2-1 edge S2-1 among edges of the second pixel opening OA2 when viewed from a direction vertical to the substrate 100. In this regard, the 2-1 edge S2-1 may not overlap the third wire 131′, and the 2-2 edge S2-2 may not overlap the fourth wire 132′.

In other words, when viewed from a direction vertical to the substrate 100, the third wire 131′ may be between the 2-1 edge S2-1 and the 2-2 edge S2-2 and thus may be apart from the 2-1 edge S2-1 and the 2-2 edge S2-2.

In addition, when viewed from a direction vertical to the substrate 100, the fourth wire 132′ may be between the 2-1 edge S2-1 and the 2-2 edge S2-2 and thus apart from the 2-1 edge S2-1 and the 2-2 edge S2-2, and may be apart from the third wire 131′ in the second direction.

The pixel-defining layer 105 may have the third pixel opening OA3 exposing a central portion of the third pixel electrode 150-3. The pixel-defining layer 105 may be disposed on the planarization layer 104 to cover the edges of the third pixel electrode 150-3. The pixel-defining layer 105 may include the 3-1 edge S3-1 extending in the first direction among edges of the third pixel opening OA3 when viewed from a direction vertical to the substrate 100, and the 3-2 edge S3-2 extending in the first direction and apart from the 3-1 edge S3-1 among edges of the third pixel opening OA3 when viewed from a direction vertical to the substrate 100. In this regard, the 3-1 edge S3-1 may overlap the first wire 131, and the 3-2 edge S3-2 may overlap the second wire 132.

The pixel-defining layer 105 may have the fourth pixel opening OA4 exposing a central portion of the fourth pixel electrode 150-4. The pixel-defining layer 105 may be disposed on the planarization layer 104 to cover the edges of the fourth pixel electrode 150-4. The pixel-defining layer 105 may include the 4-1 edge S4-1 extending in the first direction among edges of the fourth pixel opening OA4 when viewed from a direction vertical to the substrate 100, and the 4-2 edge S4-2 extending in the first direction and apart from the 4-1 edge S4-1 among edges of the fourth pixel opening OA4 when viewed from a direction vertical to the substrate 100. In this regard, the 4-1 edge S4-1 may not overlap the third wire 131′, and the 4-2 edge S4-2 may not overlap the fourth wire 132′.

In other words, when viewed from a direction vertical to the substrate 100, the third wire 131′ may be between the 4-1 edge S4-1 and the 4-2 edge S4-2 and thus may be apart from the 4-1 edge S4-1 and the 4-2 edge S4-2.

In addition, when viewed from a direction vertical to the substrate 100, the fourth wire 132′ may be between the 4-1 edge S4-1 and the 4-2 edge S4-2 and thus apart from the 4-1 edge S4-1 and the 4-2 edge S4-2, and may be apart from the third wire 131′ in the second direction.

For reference, the first voltage line 133 extending in the first direction may be arranged between the first wire 131 and the second wire 132. In addition, the second voltage line 133′ extending in the first direction may be arranged between the third wire 131′ and the fourth wire 132′, and the second voltage line 133′ may include the same material and have the same layer structure as the first voltage line 133 described above.

For reference, although the wires shown in FIG. 15 are illustrated as straight lines for convenience of description, this should not limit the scope as defined by the appended claims. The wires described herein may be modified in various forms, and may or may not overlap the edges of the pixel-defining layer 105 to control a reflow phenomenon depending on whether to overlap the edges of the pixel-defining layer 105 or not.

For reference, descriptions of the wiring shown in FIG. 15 may be replaced with at least one of the above descriptions of FIGS. 4 to 10, 13 and 14. As an example, in the case of an edge including a recessed region, a wire corresponding to the recessed region may be arranged, and this may be apparently derived from the entirety of this specification. In addition, as an example, a description of the fifth to eighth wires included in the first conductive layer in the descriptions of FIGS. 13 and 14 may also be replaced with or added to that of the fifth to eighth wires shown in FIG. 15.

According to one or more of the above embodiments, a display device for preventing or reducing reflow that occurs during the manufacture or providing of a pixel-defining layer 105 may be implemented. However, one or more embodiments are not limited by such an effect. In one or more embodiments, for example, a display device includes a substrate 100, a pixel electrode 150 of a light-emitting element, the pixel-defining layer 105 which overlaps the pixel electrode 150, a pixel opening which is defined by a plurality of edges of the pixel-defining layer 105, the pixel opening exposing the pixel electrode 150 to outside the pixel-defining layer 105, a wiring layer (130 or 160) between the substrate 100 and the pixel electrode 150, the wiring layer including a plurality of wires (such as the first to fourth wires 131 to 132′) each extending along the substrate 100 in a first direction, the plurality of wires being spaced apart from each other along a second direction crossing the first direction, a planarization layer 104 which is between the wiring layer and the pixel electrode 150, and between the wiring layer and the pixel-defining layer 105. Among the plurality of edges of the pixel-defining layer 105 which define the pixel opening, a first edge (e.g., the 1-1 edge S1-1 or the 1-2 edge S1-2) extends along the first direction, and a second edge (e.g., the 1-3 edge S1-3 or the 1-4 edge S1-4) extends along the second direction and is connected to the first edge at a corner of the pixel opening.

Referring to FIG. 3, for example, the plurality of wires of the wiring layer overlap the second edge of the pixel-defining layer 105 to define an overlapping area of the second edge (e.g., where the first wire 131 or the second wire 132 overlaps the 1-3 edge S1-3 or the 1-4 edge S1-4), together with a non-overlapping area of the second edge which is between the plurality of first wires along the second direction (e.g., where the first wire 131 or the second wire 132 does not overlap the 1-3 edge S1-3 or the 1-4 edge S1-4).

Referring to FIG. 3, the overlapping area is further defined at the corner of the pixel opening and along the first edge (e.g., the top left or the top right corner of the pixel opening is overlapped by a wire). Referring to FIG. 7, for example, the non-overlapping area is further defined at the corner of the pixel opening and along the first edge (e.g., where the top left or the top right corner of the pixel opening is not overlapped by a wire. Referring to FIG. 9, for example, the plurality of edges of the pixel-defining layer 105 includes the first edge provided in plural including a plurality of first edges spaced apart along the second direction (e.g., two vertical edges), and the second edge (e.g., one of the horizontal edges) meets the plurality of first edges a plurality of corners of the pixel opening, the plurality of corners being opposite to each other along the second direction (e.g., a left corner and a right corner). The overlapping area is further defined at one corner among the plurality of corners of the pixel opening and along one first edge among the plurality of first edges (e.g., at the left of the pixel opening in FIG. 9), and the non-overlapping area is further defined at another corner among the plurality of corners of the pixel opening, and along another first edge among the plurality of first edges (e.g., at the right of the pixel opening in FIG. 9).

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a first wiring layer on the substrate, the first wiring layer comprising a first wire and a second wire each extending along the substrate, along a first direction, the first wire and the second wire spaced apart from each other along a second direction crossing the first direction;
a planarization layer on the first wiring layer;
a first pixel electrode which is on the planarization layer;
a pixel-defining layer on the planarization layer and overlapping the first pixel electrode; and
a first pixel opening which is defined in the pixel-defining layer and exposes the first pixel electrode to outside the pixel-defining layer,
wherein the pixel-defining layer comprises:
first edges which define the first pixel opening, and
among the first edges of the pixel-defining layer:
a 1-1 edge and a 1-2 edge each extends along the first direction,
the 1-1 edge and the 1-2 edge are spaced apart from each other along the second direction, and
the 1-1 edge overlaps the first wire.

2. The display device of claim 1, wherein the 1-2 edge overlaps the second wire.

3. The display device of claim 1, wherein one edge among the 1-1 edge and the 1-2 edge includes a protruded portion which protrudes toward the other edge among the 1-1 edge and the 1-2 edge.

4. The display device of claim 3, wherein
each of the 1-1 edge and the 1-2 edge of the pixel-defining layer has a planar shape,
each of the first wire and the second wire has an edge having a planar shape,
the planar shape of the edge of the first wire corresponds to the planar shape of the 1-1 edge, and
the planar shape of the edge of the second wire corresponds to the planar shape of the 1-2 edge.

5. The display device of claim 1, wherein the first wiring layer further comprises:
a third wire and a fourth wire each extending along the substrate along the first direction, and
the first wire, the second wire, the third wire and the fourth wire in order along the second direction and spaced apart from each other along the second direction.

6. The display device of claim 5, further comprising a second pixel electrode which is on the planarization layer and is spaced apart from the first pixel electrode along the second direction,
wherein
the pixel-defining layer overlaps the second pixel electrode,
a second pixel opening is defined in the pixel-defining layer which exposes the second pixel electrode to outside the pixel-defining layer, and
the pixel-defining layer further comprises:
second edges which define the second pixel opening, and
among the second edges of the pixel-defining layer, a 2-1 edge extends along the first direction and overlaps the third wire.

7. The display device of claim 6, wherein among the second edges of the pixel-defining layer, a 2-2 edge extends along the first direction, is spaced apart from the 2-1 edge and overlaps the fourth wire.

8. The display device of claim 5, further comprising a second pixel electrode which is on the planarization layer and is spaced apart from the first pixel electrode,
wherein
the pixel-defining layer overlaps the second pixel electrode,
a second pixel opening is defined in the pixel-defining layer which exposes the second pixel electrode to outside the pixel-defining layer, and
the pixel-defining layer further comprises:
second edges which define the second pixel opening, and
among the second edges of the pixel-defining layer:
a 2-1 edge and a 2-2 edge each extend along the first direction,
the 2-1 edge and the 2-2 edge are spaced apart from each other along the second direction with the third wire therebetween, and
the 2-1 edge and the 2-2 edge are spaced apart from the third wire along the second direction.

9. The display device of claim 8, wherein
the fourth wire is between the 2-1 edge and the 2-2 edge along the second direction, and
the fourth wire is spaced apart from each of the 2-1 edge, the 2-2 edge and the third wire along the second direction.

10. The display device of claim 1, further comprising a third pixel electrode which is on the planarization layer and is spaced apart from the first pixel electrode along the first direction,
wherein
the pixel-defining layer overlaps the third pixel electrode,
a third pixel opening is defined in the pixel-defining layer which exposes the third pixel electrode to outside the pixel-defining layer, and
the pixel-defining layer further comprises:
third edges which define the third pixel opening, and
among the third edges of the pixel-defining layer a 3-1 edge extends along the first direction and overlaps the first wire.

11. The display device of claim 10, wherein among the third edges of the pixel-defining layer, a 3-2 edge extends along the first direction, is spaced apart from the 3-1 edge and overlaps the second wire.

12. The display device of claim 1, further comprising:
a second wiring layer on the substrate, the second wiring layer comprising a fifth wire and a sixth wire each extending along the substrate along the second direction, the fifth wire and the second wire spaced apart from each other along the first direction;
an organic insulating layer and an interlayer insulating layer, on the substrate; and
in order from the substrate, along a thickness direction of the display device, the interlayer insulating layer, the second wiring layer, the organic insulating layer, the first wiring layer and the planarization layer.

13. The display device of claim 12, wherein among the first edges of the pixel-defining layer which define the first pixel opening:
a 1-3 edge and a 1-4 edge each extend along the second direction,
the 1-3 edge and the 1-4 edge are spaced apart from each other along the first direction, and
the 1-3 edge overlaps the fifth wire.

14. The display device of claim 13, wherein the 1-4 edge overlaps the sixth wire.

15. The display device of claim 12, wherein
the fifth wire is between the 1-3 edge and the 1-4 edge along the first direction, and
the fifth wire is spaced apart from each of the 1-3 edge and the 1-4 edge along the first direction.

16. The display device of claim 15, wherein
the sixth wire is between the 1-3 edge and the 1-4 edge along the first direction, and
the sixth wire is spaced apart from each of the 1-3 edge, the 1-4 edge, and the fifth wire along the first direction.

17. A display device comprising:
a substrate;
a pixel electrode of a light-emitting element, on the substrate;
a pixel-defining layer which overlaps the pixel electrode;
a pixel opening which is defined by a plurality of edges of the pixel-defining layer, the pixel opening exposing the pixel electrode to outside the pixel-defining layer;
a wiring layer between the substrate and the pixel electrode, the wiring layer comprising a plurality of wires each extending along the substrate in a first direction, the plurality of wires being spaced apart from each other along a second direction crossing the first direction; and
a planarization layer which is between the wiring layer and the pixel electrode, and between the wiring layer and the pixel-defining layer;
wherein
among the plurality of edges of the pixel-defining layer which define the pixel opening:
a first edge extends along the first direction, and
a second edge extends along the second direction and is connected to
the first edge at a corner of the pixel opening, and
the plurality of wires of the wiring layer overlap the second edge of the pixel-defining layer to define an overlapping area of the second edge, together with a non-overlapping area of the second edge which is between the plurality of first wires along the second direction.

18. The display device of claim 17, wherein the overlapping area is further defined at the corner of the pixel opening and along the first edge.

19. The display device of claim 17, wherein the non-overlapping area is further defined at the corner of the pixel opening and along the first edge.

20. The display device of claim 17, wherein
the plurality of edges of the pixel-defining layer includes:
the first edge provided in plural including a plurality of first edges spaced apart along the second direction, and
the second edge which meets the plurality of first edges a plurality of corners of the pixel opening, the plurality of corners being opposite to each other along the second direction,
the overlapping area is further defined at one corner among the plurality of corners of the pixel opening, and along one first edge among the plurality of first edges, and
the non-overlapping area is further defined at another corner among the plurality of corners of the pixel opening, and along another first edge among the plurality of first edges.
